(19) United States
(12) Patent Application Publication
(10) Pub. No.: US 2020/0373507 A1
(43) Pub. Date: Nov. 26, 2020

(54) Apparatus For Immersion-Based Preparation of Perovskite Thin Film, Use Method and Application Thereof

(71) Applicant: Hangzhou Microquanta Semiconductor Co., Ltd., Hangzhou, Zhejiang (CN)

(72) Inventors: Jizhong Yao, Hangzhou, Zhejiang (CN); Buyi Yan, Hangzhou, Zhejiang (CN); Rui Sheng, Hangzhou, Zhejiang (CN); Nannan Gu, Hangzhou, Zhejiang (CN)

(21) Appl. No.: 16/960,361

(22) PCT Filed: Dec. 21, 2018
(86) PCT No.: PCT/CN2018/122633

§ 371 Date: Jul. 7, 2020

(30) Foreign Application Priority Data
Jan. 17, 2018 (CN) 201810046196.6

(51) Int. Cl. H01L 51/42; H01L 51/00

(52) U.S. Cl. CPC H01L 51/4226; H01L 2251/10; H01L 51/0026

(57) ABSTRACT

The invention relates to an apparatus for immersion-based preparation of a perovskite thin film, including a sealed cavity (1). The sealed cavity (1) is internally provided with at least one semi-enclosed reactor device (2) therein, the semi-enclosed reactor device (2) includes a lower heating and sublimation device (3) and an upper heating station (4), a container (5) is provided at the top of the lower heating and sublimation device, the container (5) contains a reactant precursor, a substrate frame (6) is provided directly above the container (5), the substrate frame (6) covers an opening of the container (5), a substrate frame support platform (7) is provided at a side surface of the container (5), the substrate frame (6) is disposed on the substrate frame support platform (7), a substrate (8) to be deposited is provided at a lower bottom surface of the substrate frame (6), a surface to be deposited of the substrate (8) directly faces the reactant precursor in the container (5), and the upper heating station (4) is disposed on the substrate frame (6) to heat the substrate (8). The invention further discloses a method for preparing a perovskite solar cell by using the apparatus for immersion-based preparation of a perovskite thin film. Crystal growth of the thin film can be controlled in the preparation process, and the film formation quality, and uniformity and repeatability are improved.

### TECHNICAL FIELD

The invention belongs to the technical field of perovskite solar cells, and particularly relates to an apparatus for immersion-based preparation of a perovskite thin film, and a use method and application thereof.

### BACKGROUND

A solar cell is a photoelectric conversion device that converts solar energy into electrical energy by using the photovoltaic effect of semiconductors. So far, solar power generation has become the most important renewable energy source besides hydraulic power generation and wind power generation. Semiconductors currently used for commercialization include monocrystalline silicon, polycrystalline silicon, amorphous silicon, cadmium telluride, copper indium gallium selenide and the like, but most of them are high in energy consumption and high in cost.

In recent years, aperovskite solar cell has drawn widespread attention. Perovskite solar cell uses organo-metal halide material as a light absorbing layer. Perovskite has an ABX₃ type cubic octahedral structure, as shown in FIG. 1. The thin film solar cell prepared by this material has the advantages of straightforward process, low production cost, high stability and high conversion rate. Since 2009, its photoelectric conversion efficiency has increased from 3.8% to above 22%, which is higher than that of commercialized crystalline silicon solar cells. Thus, the thin film solar cell has greater cost advantages.

Various existing thin film forming processes of perovskite solar cells can be divided into two categories: solution based method and vapor based method. Solution based method is easy to operate, but uniformity of the as formed thin film is poor and process repeatability is questionable, all affecting the efficiency of the solar cell. Vapor based method includes dual source co-evaporation method, vapor-assisted solution method, chemical vapor deposition (CVD) method and other methods. Among them, vapor-assisted solution method can be used for preparing uniform perovskite thin film with large grain size and small surface roughness, but process repeatability and as formed film quality need to be improved.

### SUMMARY

The technical problem to be solved by the present invention is to provide an apparatus for immersion-based preparation of a perovskite thin film, and a use method and application thereof. A uniform and stable reaction environment is provided in the present disclosure so that crystal growth of the thin film can be controlled in the preparation process, the as formed film quality and uniformity and process repeatability are improved, and thus, the present disclosure can be embedded into a large-scale production line for continuous production.

The present invention is realized by providing an apparatus for immersion-based preparation of a perovskite thin film, including a sealed cavity. The sealed cavity is internally provided with at least one semi-enclosed reactor device therein, the semi-enclosed reactor device includes a lower heating and sublimation device and an upper heating station, a container with an opening facing upward is provided at the top of the lower heating and sublimation device, the container contains a reactant precursor, a substrate frame is provided directly above the container, the substrate frame covers an opening of the container, a substrate frame support platform is provided at a side surface of the container, the substrate frame is disposed on the substrate frame support platform, a substrate to be deposited is provided at a lower bottom surface of the substrate frame, the substrate is located directly above the container, a surface to be deposited of the substrate directly faces the reactant precursor in the container, the upper heating station is disposed on the substrate frame to heat the substrate, and the reactant precursor is evaporated and deposited onto the surface of the substrate; and a vacuum pressure in the sealed cavity is controlled, and heating temperatures of the upper heating station and the lower heating and sublimation device are controlled.

Further, an area of the opening of the container is greater than an area of the substrate.

Further, the substrate frame may drive the substrate to reciprocate back and forth in a horizontal or vertical direction.

Further, a thickness of the reactant precursor in the container is 2-10 mm with a thickness non-uniformity not exceeding 0.1-1.0 mm; and a height distance between the surface to be deposited of the substrate and a top surface of the reactant precursor is 5-40 mm.

Further, a vacuum pressure range in the sealed cavity is 10⁻⁵ Pa-10⁵ Pa, a heating temperature range of the upper heating station is 20-400° C., a heating temperature range of the lower heating and sublimation device is 20-400° C., and a reaction time is 10-120 min.

Further, the sealed cavity is a small-scale cavity or a large-scale continuous production apparatus, and the vacuum pressure in the sealed cavity is controlled by a vacuum pump and a vacuum valve.

The present invention is realized by further providing a use method of the apparatus for immersion-based preparation of a perovskite thin film as described above, including the following steps:

at step 1, pouring a reactant precursor material into a container, disposing a substrate on an inner bottom surface of a substrate frame with a surface to be deposited of the substrate facing downward, placing the substrate frame on a substrate frame support platform, and then putting a well-set semi-enclosed reactor device into a sealed cavity;

at step 2, extracting air in the sealed cavity to control a vacuum pressure in the sealed cavity; respectively energizing an upper heating station and a lower heating and sublimation device to control heating temperatures of the upper heating station and the lower heating and sublimation device such that the reactant precursor is evaporated and deposited onto the surface of the substrate; and

at step 3, after continuing the reaction for 10-120 min, deenergizing the upper heating station and the lower heating and sublimation device to stop heating, restoring the sealed cavity to an atmospheric pressure, and taking out the substrate deposited with the reactant precursor.

Further, at step 1, a thickness of the reactant precursor in the container is 2-10 mm with a thickness non-uniformity not exceeding 0.1-1.0 mm, and a height distance between the surface to be deposited of the substrate and a top surface of the reactant precursor is 5-40 mm.

Further, at step 2, the substrate frame may drive the substrate to reciprocate back and forth in a horizontal or vertical direction.

Further, at step 2, the sealed cavity is a small-scale cavity or a large-scale continuous production apparatus, and the vacuum pressure in the sealed cavity is controlled by a vacuum pump and a vacuum valve.

Further, at step 2, a vacuum pressure range in the sealed cavity is 10⁻⁵ Pa-10⁵ Pa, a heating temperature range of the upper heating station is 20-400° C., and a heating temperature range of the lower heating and sublimation device is 20-400° C.

The present invention is realized by further providing a perovskite solar cell, wherein the perovskite solar cell includes a perovskite layer, and the apparatus for immersion-based preparation of a perovskite thin film as described above is used in a preparation process of the perovskite layer.

The present invention is realized by further providing a preparation method of the perovskite solar cell as described above, wherein the perovskite solar cell includes a first conductive electrode, a first transport layer, a perovskite thin film layer, a second transport layer and a second conductive electrode. The preparation method including the following steps S1-S6:

at step S1, preparing the first transport layer on the first conductive electrode;

at step S2, depositing one or more metal halide BX₂ thin films on a substrate deposited with the first transport layer by any processing method of spin coating, blade coating, slot die continuous coating, spray coating, printing or vacuum deposition;

at step S3, fixing the substrate deposited with the metal halide BX₂ thin film, as a substrate to be deposited, to a substrate frame of the apparatus for immersion-based preparation of a perovskite thin film as described above, placing one or more reactants AX in a container and flattening each reactant AX uniformly with the surface to be deposited of the substrate directly facing the reactant AX in the container, heating an upper heating station and a lower heating and sublimation device at the same time, controlling an vacuum pressure in the sealed cavity, and controlling heating temperatures of the upper heating station and the lower heating and sublimation device such that the reactant AX is evaporated and deposited onto the surface of the substrate containing the metal halide BX₂ to produce the perovskite thin film layer;

at step S4, after the reaction is finished, taking out the deposited substrate;

at step S5, depositing the second transport layer on the prepared perovskite thin film layer; and

at step S6, depositing the second conductive electrode.

In the metal halide BX₂, B is any one of divalent metal cations: lead, tin, tungsten, copper, zinc, gallium, germanium, arsenic, selenium, rhodium, palladium, silver, cadmium, indium, antimony, osmium, iridium, platinum, gold, mercury, thallium, bismuth and polonium, and X is any anion of chlorine, bromine, iodine, thiocyanate, cyanide and oxycyanide; a thickness of the metal halide BX₂ thin film is 80-300 nm.

In the reactant AX, A is any cation of cesium, rubidium, potassium, amino, amidino or alkali group, and X is any anion of chlorine, bromine, iodine, thiocyanate, cyanide and oxycyanide.

Further, a thickness of the reactant precursor in the container is 2-10 mm, a thickness non-uniformity of each reactant precursor does not exceed 0.1-1.0 mm, and a height distance between the surface to be deposited of the substrate and a top surface of the reactant precursor is 5-40 mm; and a vacuum pressure range in the sealed cavity is 10⁻⁵ Pa-10⁵ Pa, a heating temperature range of the upper heating station is 100-400° C., a heating temperature range of the lower heating and sublimation device is 100-400° C., and a thickness of the prepared perovskite thin film layer is 100-600 nm.

Further, the substrate frame may drive the substrate to reciprocate back and forth in a horizontal or vertical direction.

Further, the sealed cavity is a small-scale cavity or a large-scale continuous production apparatus, and the vacuum pressure in the sealed cavity is controlled by a vacuum pump and a vacuum valve.

Compared with the prior art, the apparatus for immersion-based preparation of a perovskite thin film, and a use method and application thereof of the present invention provide a uniform and stable reaction environment, so that crystal growth of the thin film can be controlled in the preparation process of the perovskite thin film, the film formation quality, and uniformity and repeatability are improved, and thus the present invention can be embedded into a large-scale production line for continuous production.

Compared with the prior art, the present invention also has the following characteristics:

1. The quality of the perovskite thin film to be formed can be accurately controlled, and the uniformity of the perovskite thin film is improved.

2. A complete reaction of the metal halide and the halide vapor is promoted, and the controllability of perovskite crystallization is improved.

3. A solution capable of realizing continuous production is provided.

4. The deposition rate and the material utilization ratio are improved.

5. The deposition under vacuum prevents the perovskite material against decomposition or deterioration.

### BRIEF DESCRIPTION OF THE DRAWINGS

FIG. 1 is a schematic diagram of a molecular structure of a perovskite thin film in the prior art.

FIG. 2 is a schematic plan view of a preferred embodiment of an apparatus for immersion-based preparation of a perovskite thin film of the present invention.

FIG. 3 is a schematic plan view of a preferred embodiment of a semi-enclosed device in FIG. 2.

FIG. 4 is a schematic diagram of a preferred embodiment of a substrate frame in FIG. 3.

FIG. 5 is a preparation flow chart of a perovskite thin film in a perovskite solar cell of the present invention.

FIG. 6 is a scanning electron micrograph of a perovskite thin film prepared by using the apparatus for immersion-based preparation of a perovskite thin film of the present invention.

FIG. 7 is a JV curve of the perovskite solar cell prepared by using the apparatus for immersion-based preparation of a perovskite thin film of the present invention.

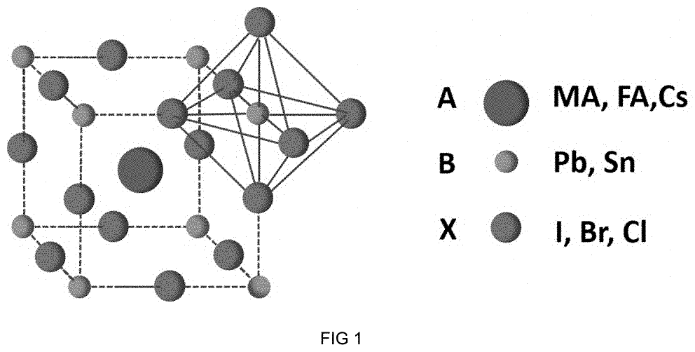

### DETAILED DESCRIPTION OF THE EMBODIMENTS

In order to make the technical problems to be solved, technical solutions and advantageous effects of the invention clearer, the present invention will be described in detail below with reference to the accompanying drawing and embodiments. It should be understood that the specific embodiments described herein are merely illustrative of the present invention and are not intended to limit the invention.

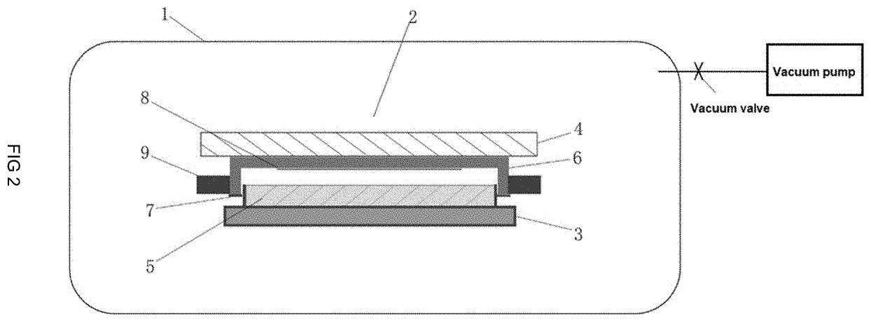

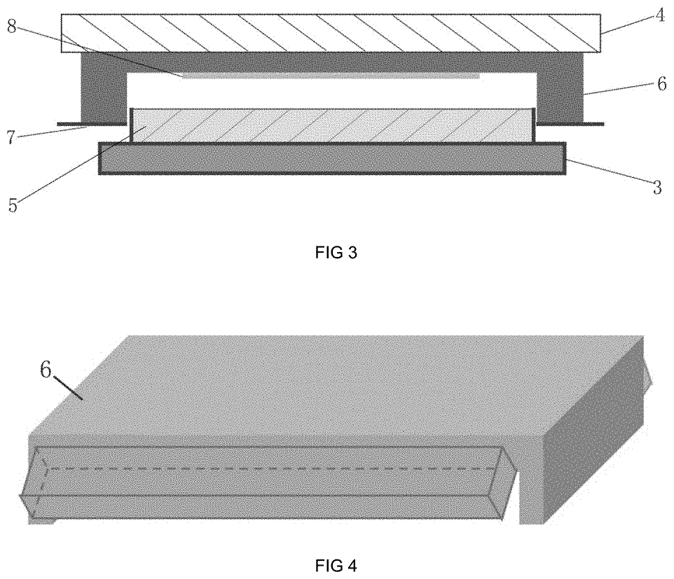

With reference to FIG. 2, FIG. 3 and FIG. 4 at the same time, an apparatus for immersion-based preparation of a perovskite thin film according to the present invention includes a sealed cavity 1, wherein the sealed cavity 1 is internally provided with at least one semi-enclosed reactor device 2.

The semi-enclosed reactor device 2 includes a lower heating and sublimation device 3 and an upper heating station 4. A container 5 with an opening facing upward is provided at the top of the lower heating and sublimation device 3. The container 5 contains a reactant precursor. A substrate frame 6 is provided directly above the container 5. The substrate frame 6 covers an opening of the container 5. A substrate frame support platform 7 is provided at a side surface of the container 5. The substrate frame 6 is disposed on the substrate frame support platform 7. A substrate 8 to be deposited is provided at a lower bottom surface of the substrate frame 6, the substrate 8 is located directly above the container 5, and a surface to be deposited of the substrate 8 directly faces the reactant precursor in the container 5. The upper heating station 4 is disposed on the substrate frame 6 to heat the substrate 8. The reactant precursor is evaporated and deposited onto the surface of the substrate 8. An vacuum pressure in the sealed cavity 1 is controlled, and heating temperatures of the upper heating station 4 and the lower heating and sublimation device 3 are controlled. The upper heating station 4 is disposed at the top of the substrate frame 6, a reactant heating device for heating the reactant precursor in the container 5 is disposed in the lower heating and sublimation device 3, and a substrate heating device for heating the substrate 8 is disposed on the upper heating station 4.

An area of the opening of the container 5 is greater than an area of the substrate 8. A thickness of the reactant precursor in the container 5 is 2-10 mm, with a thickness non-uniformity not exceeding 0.1-1.0 mm. A height distance between the surface to be deposited of the substrate 8 and a top surface of the reactant precursor is 5-40 mm.

A vacuum pressure range in the sealed cavity 1 is 10⁻⁵ Pa-10⁵ Pa, a heating temperature range of the upper heating station 4 is 20-400° C., a heating temperature range of the lower heating and sublimation device 3 is 20-400° C., and a reaction time is 10-120 min.

The apparatus for immersion-based preparation of a perovskite thin film of the present invention further includes a transmission device 9, wherein the transmission gear 9 drives the substrate frame support platform 7 such that the substrate frame 6 reciprocate back and forth in a horizontal direction or vertical direction.

The sealed cavity 1 of the present invention is a small-scale cavity or a large-scale continuous production apparatus. The vacuum pressure in the sealed cavity 1 is controlled by a vacuum pump and a vacuum valve.

The invention further discloses a use method of the apparatus for immersion-based preparation of a perovskite thin film as described above, and the method includes the following step s1-3.

At step 1, a reactant precursor material is poured into a container 5, a substrate 8 is disposed on an inner bottom surface of a substrate frame 6 with a surface to be deposited of the substrate facing downward, the substrate frame 6 is disposed on a substrate frame support platform 7, and then a well-set semi-enclosed reactor device 2 is put into a sealed cavity 1.

At step 2, air in the sealed cavity 1 is extracted to control an vacuum pressure in the sealed cavity 1, and an upper heating station 4 and a lower heating and sublimation device 3 are respectively energized to control heating temperatures of the upper heating station 4 and the lower heating and sublimation device 3 such that the reactant precursor is evaporated and deposited onto the surface of the substrate 8.

At step 3 after the reaction is continued for 10-120 min, the upper heating station 4 and the lower heating and sublimation device 3 are de-energized to stop heating an atmospheric pressure is restored in the sealed cavity 1, and the substrate 8 deposited with the reactant precursor is taken out.

At step 1, a thickness of the reactant precursor in the container 5 is 2-10 mm with a thickness non-uniformity not exceeding 0.1-1.0 mm, and a height distance between the surface to be deposited of the substrate 8 and a top surface of the reactant precursor is 5-40 mm.

At step 2, a vacuum pressure range in the sealed cavity 1 is 10⁻⁵ Pa-10⁵ Pa, a heating temperature range of the upper heating station 4 is 20-400° C., and a heating temperature range of the lower heating and sublimation device 3 is 20-400° C.

At step 2, the substrate frame 6 may drive the substrate 8 to reciprocate back and forth in a horizontal or vertical direction.

At step 2, the sealed cavity is a small-scale cavity or a large-scale continuous production apparatus, and the vacuum pressure in the sealed cavity is controlled by a vacuum pump and a vacuum valve.

The present invention further discloses a perovskite solar cell, wherein the perovskite solar cell includes a perovskite layer, and the apparatus for immersion-based preparation of a perovskite thin film as described above is used in a preparation process of the perovskite layer.

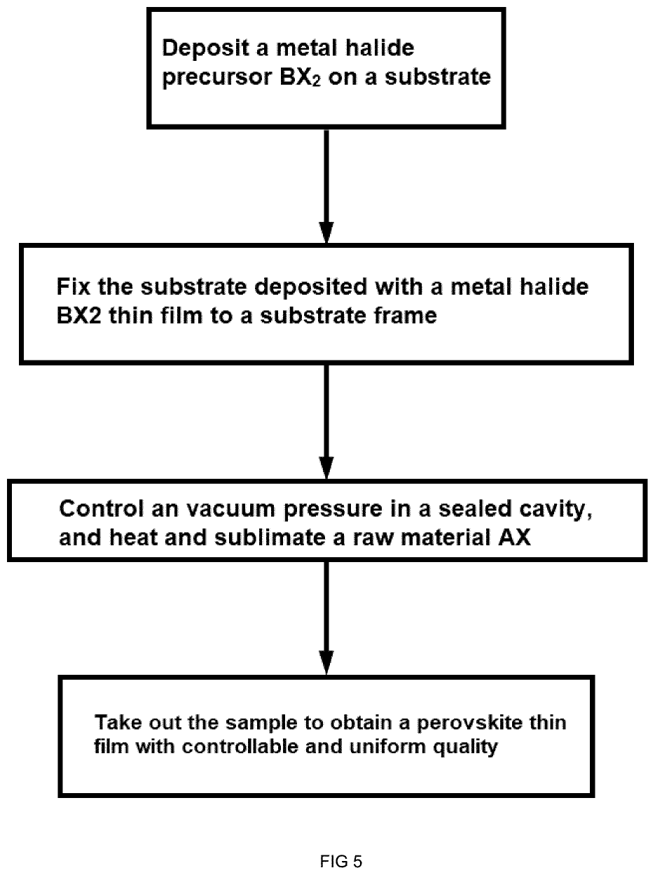

With reference to FIG. 5, the present invention further discloses a preparation method of a perovskite solar cell, wherein the perovskite solar cell includes a first conductive electrode, a first transport layer, a perovskite thin film layer, a second transport layer and a second conductive electrode. The preparation method includes the following steps S1-S6.

At step S1, the first transport layer is prepared on the first conductive electrode.

At step S2, one or more metal halide BX₂ thin films is deposited on a substrate deposited with the first transport layer by any processing method of spin coating, blade coating, slot die continuous coating, spray coating, printing or vacuum deposition.

At step S3, the substrate 8 deposited with the metal halide BX₂ thin film is fixed, as a substrate to be deposited, to a substrate frame 6 of the apparatus for immersion-based preparation of a perovskite thin film as described above, one or more reactants AX is placed in the container 5 and flattened each uniformly while the surface to be deposited of the substrate 8 faces downward the reactant AX in the container 5, the upper heating station 4 and the lower heating and sublimation device 3 are heated at the same time, the vacuum pressure in the sealed cavity 1 is controlled, and heating temperatures of the upper heating station 4 and the lower heating and sublimation device 3 are controlled such that the reactant AX is evaporated and deposited onto the surface of the substrate 8 containing the metal halide BX₂ to produce the perovskite thin film layer.

At step S4, after the reaction is finished, the deposited substrate 8 is taken out.

At step S5, the second transport layer is deposited on the perovskite thin film layer of the substrate 8.

At step S6, the second conductive electrode is deposited.

In the metal halide BX₂, B is any one of divalent metal cations: lead (Pb²⁺), tin (Sn²⁺), tungsten (W²⁺), copper (Cu²⁺), zinc (Zn²⁺), gallium (Ga²⁺), germanium (Ge²⁺), arsenic (As²⁺), selenium (Se²⁺), rhodium (Rh²⁺), palladium (Pd²⁺), silver (Ag²⁺), cadmium (Cd²⁺), indium (In²⁺), antimony (Sb²⁺), osmium (Os²⁺), iridium (Ir²⁺), platinum (Pt²⁺), gold (Au²⁺), mercury (Hg²⁺), thallium (Tl²⁺), bismuth (Bi²⁺) and polonium (Po²⁺), and X is any anion of chlorine (Cl⁻), bromine (Br), iodine (I), thiocyanate (NCS), cyanide (CN⁻) and oxycyanide (NCO); and a thickness of the metal halide BX₂ thin film is 80-300 nm.

In the reactant AX, A is any cation of cesium (CO, rubidium (Rb⁺), potassium (K⁻), amino, amidino or alkali group, and X is any anion of chlorine (Cl⁻), bromine (Bi⁻), iodine (I⁻), thiocyanate (NCS⁻), cyanide (CN⁻) and oxycyanide (NCO⁻).

A thickness of the reactant precursor in the container 5 is 2-10 mm with a thickness non-uniformity of each reactant precursor not exceeding 0.1-1.0 mm, and a height distance between the surface to be deposited of the substrate 8 and a top surface of the reactant precursor is 5-40 mm. A vacuum pressure range in the sealed cavity 1 is 10⁻⁵ Pa-10⁵ Pa, a heating temperature range of the upper heating station 4 is 100-400° C., a heating temperature range of the lower heating and sublimation device 3 is 100-400° C., and a thickness of the prepared perovskite thin film layer is 100-600 nm.

The substrate frame 6 may drive the substrate 8 to reciprocate back and forth in a horizontal or vertical direction.

The sealed cavity is a small-scale cavity or a large-scale continuous production apparatus, and the vacuum pressure in the sealed cavity 1 is controlled by a vacuum pump and a vacuum valve.

The method for preparing the perovskite solar cell by using the apparatus for immersion-based preparation of a perovskite thin film of the present invention will be described below with reference to specific embodiments.

### Embodiment 1

A preparation method of a perovskite solar cell included the following steps:

(1) a 10×10 cm ITO glass plate was subjected to ultrasonic cleaning sequentially with a detergent, deionized water, acetone and isopropanol for 30 min each, then blow-dried with N₂ and treated with UV O-zone for 10 min;

(2) a PEDOT:PSS thin film was prepared as a hole transport layer;

(3) a metal halide thin film precursor solution was prepared: 461 mg of PbI₂ (1 mmol) was dissolved in 1 mL of DMF solution, heating and stirring were performed at 60° C. for 2 h, and the mixture was for later use after the dissolution;

(4) a doped PbI₂ thin film was prepared by using the prepared precursor solution by slot die coating;

(5) a substrate 8 deposited with a metal halide thin film was fixed to a substrate frame 6 with a surface to be deposited facing downward, a reaction cavity upper cover was transmitted by a transmission device to be directly above an evaporating dish fully covered with methyl ammonium iodide (MAI) such that the reaction cavity upper cover was disposed above the substrate frame support platform 7, vacuumizing was performed by a vacuum pump to control the vacuum pressure, a feedback was given to the vacuum valve to close the vacuum valve after the gas pressure reached a certain value, an vacuum pressure range in a cavity body of a sealed cavity 1 was 10⁻⁵ Pa-10⁵ Pa, a heating temperature of a lower heating and sublimation device 3 was controlled at 100° C.-200° C., and a heating temperature of an upper heating station 4 was controlled at 100° C.-200° C. such that MAI gas molecules reacted with PbI₂ to produce a perovskite thin film, wherein a reaction time was 10-120 min;

(6) an electron transport layer PCBM was deposited; and

(7) a metal conductive layer Ag electrode was evaporated to obtain the perovskite solar cell.

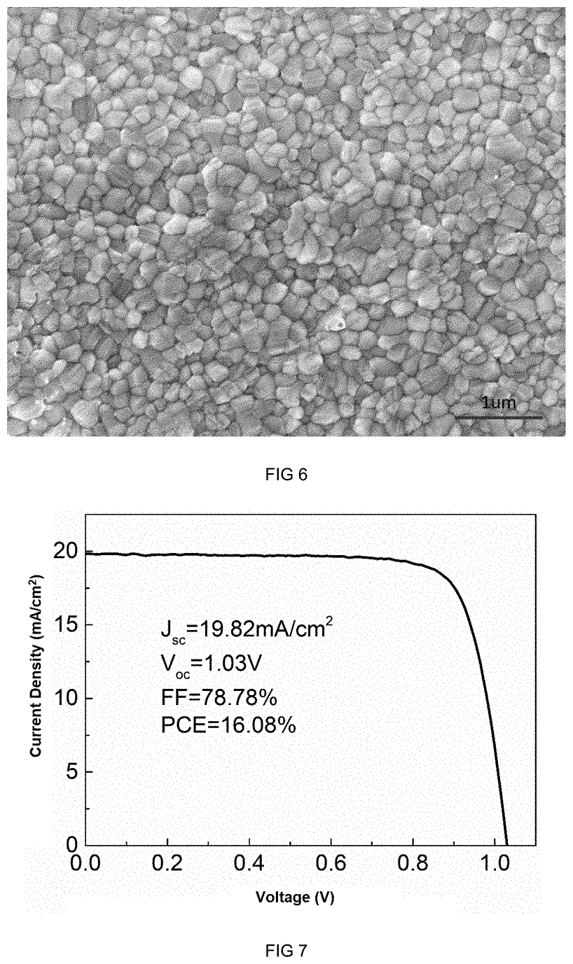

FIG. 6 is a scanning electron micrograph of a perovskite thin film prepared by using an apparatus for immersion-based preparation of a perovskite thin film of the present invention. It can be seen from the figure that the perovskite prepared by this method is smooth and dense and has uniform crystal particle size.

FIG. 7 is a JV curve of a perovskite solar cell prepared by using an apparatus for immersion-based preparation of a perovskite thin film of the present invention. A cell efficiency reaches 16.08% (PCE).

The above description is only the preferred embodiments of the invention and is not intended to limit the present invention. Any modifications, equivalent substitutions and improvements made within the spirit and scope of the invention should be included within the protection scope of the invention.

1. An apparatus for immersion-based preparation of a perovskite thin film, comprising:
a sealed cavity,
at least one semi-enclosed reactor device within the sealed cavity, the semi-enclosed reactor device comprising a lower heating and sublimation device and an upper heating station,
a container with an opening facing upward at the top of the lower heating and sublimation device, the container being configured to receive a reactant precursor,
a substrate frame above the container, the substrate frame covering an opening of the container,
a substrate frame support platform at a side surface of the container, the substrate frame being disposed on the substrate frame support platform, and
wherein the apparatus is configured to receive a substrate at a lower bottom surface of the substrate frame and above the container such that one surface of the substrate faces the container,
wherein the upper heating station is disposed on the substrate frame and is configured to heat the substrate such that, during use, the reactant precursor is evaporated and deposited onto the surface of the substrate.

2. The apparatus according to claim 1, wherein an area of the opening of the container is greater than an area of the substrate.

3. The apparatus according to claim 1, wherein the substrate frame is capable of driving the substrate to reciprocate back and forth in a horizontal or vertical direction.

4-5. (canceled)

6. The apparatus according to claim 1, further comprising a vacuum pump and a vacuum valve that are configured to control the pressure in the sealed cavity.

7. A method of forming a substrate deposited with a reactant precursor by using the apparatus according to claim 1, comprising the following steps:
step 1: pouring a reactant precursor into the container, and disposing a substrate on the lower bottom surface of the substrate frame with a surface to be deposited facing the container;
step 2: extracting air in the sealed cavity to reduce the pressure in the sealed cavity; heating the reactant precursor by using the upper heating station and the lower heating and sublimation device such that the reactant precursor is evaporated and deposited onto the surface of the substrate facing the container; and
step 3: after stopping heating and restoring the sealed cavity to an atmospheric pressure, removing the substrate deposited with the reactant precursor from the sealed cavity.

8. The method according to claim 7, wherein in step 1, a thickness of the reactant precursor in the container is 2-10 mm with a thickness non-uniformity not exceeding 0.1-1.0 mm, and a distance between the surface of the substrate facing the container and a top surface of the reactant precursor is 5-40 mm.

9. The method according to claim 7, wherein the substrate frame is capable of driving the substrate to reciprocate back and forth in a horizontal or vertical direction.

10. The method according to claim 7, wherein in step 2, the pressure in the sealed cavity is controlled by a vacuum pump and a vacuum valve.

11. The method according to claim 7, wherein in step 2, a vacuum pressure range in the sealed cavity is 10⁻⁵ Pa-10⁵ Pa, a heating temperature range of the upper heating station is 20-400° C., and a heating temperature range of the lower heating and sublimation device is 20-400° C.

12. A perovskite solar cell, comprising a perovskite layer prepared by the apparatus according to claim 1.

13. A preparation method of a perovskite solar cell using the apparatus according to claim 1, wherein the perovskite solar cell comprises a substrate, a first conductive electrode, a first transport layer, a perovskite thin film layer, a second transport layer and a second conductive electrode, and the preparation method comprises the following steps:
step S1: preparing the first transport layer on the first conductive electrode, wherein the first conductive electrode is supported by the substrate;
step S2: depositing one or more metal halide BX₂ thin films on the first transport layer by spin coating, blade coating, slot die continuous coating, spray coating, printing or vacuum deposition to form an intermediate substrate;
step S3: fixing the intermediate substrate, as a substrate to be received by the apparatus, to the substrate frame such that the surface containing BX₂ faces the container, placing one or more reactants AX in the container, reducing the pressure in the sealed cavity, and heating the reactant AX by using the upper heating station and the lower heating and sublimation device such that the reactant AX is evaporated and deposited onto the surface of the substrate containing the metal halide BX₂ to produce the perovskite thin film layer;
step S4: removing the deposited substrate from the sealed cavity;
step S5: depositing the second transport layer on the perovskite thin film layer; and
step S6: depositing the second conductive electrode on the second transport layer;
wherein in the metal halide BX₂, B is a cation of a divalent metal: selected from the group consisting of lead, tin, tungsten, copper, zinc, gallium, germanium, arsenic, selenium, rhodium, palladium, silver, cadmium, indium, antimony, osmium, iridium, platinum, gold, mercury, thallium, bismuth and polonium, and X independently is a chlorine, bromine, iodine, thiocyanate, cyanide or oxycyanide anion;
the metal halide BX₂ thin film has a thickness of 80-300 nm; and
in the reactant AX, A is a cesium, rubidium, potassium, amino, amidino or alkali cation, and X independently is a chlorine, bromine, iodine, thiocyanate, cyanide or oxycyanide cation.

14. The preparation method according to claim 13, wherein, in step S3, a thickness of the reactant precursor in the container is 2-10 mm, a thickness non-uniformity of each reactant precursor does not exceed 0.1-1.0 mm, and a distance between the surface of the substrate facing the container and a top surface of the reactant precursor is 5-40 mm; and a vacuum pressure range in the sealed cavity is 10⁻⁵ Pa-10⁵ Pa, a heating temperature range of the upper heating station is 100-400° C., a heating temperature range of the lower heating and sublimation device is 100-400° C., and a thickness of the prepared perovskite thin film layer is 100-600 nm.

15. The preparation method according to claim 13, wherein the substrate frame is capable of driving the substrate to reciprocate back and forth in a horizontal or vertical direction.

16. The preparation method according to claim 13, wherein, in step S3, the vacuum pressure in the sealed cavity is controlled by a vacuum pump and a vacuum valve.
